(19) United States
(12) Patent Application Publication
(10) Pub. No.: US 2007/0186413 A1
(43) Pub. Date: Aug. 16, 2007

(54) Circuit board structure and method for fabricating the same

(76) Inventor: Shih-Ping Hsu, Hsin-chu (TW)

Correspondence Address: Mr. Joseph A. Sawyer, Jr.;SAWYER LAW GROUP LLP, Suite 406, 2465 East Bayshore Road, Palo Alto, CA, 94303, US

(21) Appl. No.: 11/543,545

(22) Filed: Oct. 4, 2006

(30) Foreign Application Priority Data
Feb. 8, 2006 (TW) 095104170

(51) Int. Cl. H05K 1/16

(52) U.S. Cl. 29/830; 29/846; 29/831; 29/852; 174/260

(57) ABSTRACT

A circuit board structure and method for fabricating the same are proposed. A core board with a plurality of openings formed therein is provided. Conductive columns are formed in the openings of the core board. Dielectric layers are formed on surfaces of the core board respectively and a plurality of openings are formed in the dielectric layers corresponding in position to the conductive columns in the core board. Circuit layers are formed on surfaces of the dielectric layers, and conductive structures electrically connected to the conductive columns are formed in the openings of the dielectric layers. Thereby, the circuit layers are electrically connected together through the conductive columns in the core board. Therefore, the present invention eliminates the need for electrically conductive pads and increases the layout space. The present invention can be applied in circuit boards with high layout density requirement.

### CROSS-REFERENCE TO RELATED APPLICATION

This application claims benefit under 35 USC 119 to Taiwan Application No. 095104170, filed Feb. 8, 2006.

### FIELD OF THE INVENTION

The present invention relates generally to a circuit board structure and fabrication method thereof, and more particularly to a high-density circuit board structure and fabrication method thereof.

### BACKGROUND OF THE INVENTION

Currently, with rapid development of the electronic industry, the R&D effort is being focused on multi-functional and high-performance electronic products. Accordingly, circuit boards with high-density circuit layout are required. Therefore, how to realize high-density circuit layout in limited area of circuit boards or substrates has become a research object.

FIGS. 1A and 1B are sectional diagrams of a conventional circuit board structure. As shown in FIG. 1A, a core board 11 made of such as resin coated copper is prepared. The core board 11 has circuit layers 112 formed on two surfaces thereof. Plating through holes 110 are formed in the core board 11 such that the circuit layer 112 on the two surfaces of the core board 11 can be electrically connected together through the plating through holes 110. Electrically conductive pads 110a are formed on the two surfaces of the core board 11 extending from the ends of the plating through holes 110.

As shown in FIG. 1B, circuit build-up layers are respectively formed on the circuit layers 112. Therein, dielectric layers 12 are respectively formed on the surfaces of the core board 11 and the circuit layers 112. A plurality of openings 120 is formed in the dielecric layers 12 corresponding in position to the electrically conductive pads 110a. Further, circuit layers 13 are respectively formed on the dielectric layers 12, and conductive blind vias 131 are formed in the openings 120 of the dielectric layers 12 and electrically connected to the electrically conductive pads 110a. Thus, the circuit layers 13 are electrically connected together through the conductive blind vias 131 and the plating through holes 110.

However, since the conductive blind vias 131 are electrically connected to the electrically conductive pads 110a extending from the plating through holes 110, the conductive blind vias 131 are not aligned with the plating through holes 110, e.g. there exist position deviations therebetween. Thus, the size of the electrically conductive pads 110a is generally far bigger than that of the connecting portion of the conductive blind vias 131. Thereby, much more space is occupied by the electrically conductive pads, which makes it difficult to meet the requirement for high-density circuit layout.

Furthermore, to fabricate the electrically conductive pads 110a, the circuit layers 112 on the two surfaces of the core board 11 need to be patterned, which accordingly increases the fabrication cost.

Therefore, there is a need to provide a circuit board structure and fabrication method thereof that can overcome the above drawbacks.

### SUMMARY OF THE INVENTION

According to the above drawbacks, an objective of the present invention is to provide a circuit board structure and fabrication method thereof so as to increase circuit layout density.

Another objective of the present invention is to provide a circuit board structure and fabrication method thereof which eliminates the need of fabricating electrically conductive pads for electrical connection and accordingly reduces the cost.

A further objective of the present invention is to provide a circuit board structure and fabrication method thereof applicable to ultra-thin, high-density IC substrates.

Still another objective is to provide a circuit board structure and fabrication method thereof that can improve the electrical performance through solid conductive columns electrically connecting the circuit structures at two sides thereof.

In order to attain the above and other objectives, the present invention discloses a fabrication method of a circuit board structure, which comprises the steps of: preparing a core board having a plurality of openings; forming conductive columns in the openings of the core board; forming dielectric layers on surfaces of the core board; forming a plurality of openings in the dielectric layers corresponding in position to the conductive columns; and forming circuit layers on surfaces of the dielectric layers and forming conductive structures electrically connected to the conductive columns in the openings of the dielectric layers such that the circuit layers are electrically connected together through the conductive columns of the core board.

Since the circuit layers on the two surfaces of the core board are electrically connected together directly through the conductive columns that are aligned from up to down, thereby eliminating the need of fabricating electrically conductive pads as in the conventional art and overcoming the conventional drawback of big size electrically conductive pads. The circuit layout density is increased and the fabrication cost is decreased.

The core board can be a dielectric layer having a first surface and a second surface with thin metal layers formed thereon. A plurality of openings is formed in the dielectric layer penetrating through the thin metal layers on the first and second surfaces of the dielectric layer. The fabrication method of the conductive columns in such a core board comprises the steps of: forming conductive layers in the openings of the dielectric layers and on surfaces of the thin metal layers; forming metal layers on surfaces of the conductive layers and forming conductive structures in the openings; and removing the metal layers, conductive layers and thin metal layers on the first and second surfaces of the dielectric layer.

Alternatively, the core board is a dielectric layer having a first and a second surfaces with thin metal layers formed thereon, and a plurality of openings is formed in the dielectric layer penetrating through the thin metal layer on the second surface but without penetrating through the thin metal layer on the first surface. The fabrication method of the conductive columns in such a core board comprises the steps of: forming metal layers on surfaces of the thin metal layers, and forming conductive columns in the openings; and removing the metal layers and the thin metal layers on the first and second surfaces.

Alternatively, the core board is a dielectric layer having a first and a second surfaces, a thin metal layer is formed on the first surface, and a plurality of openings is formed in the dielectric layer penetrating through the second surface but without penetrating through the thin metal layer on the first surface. The fabrication method of the conductive columns in such a core board comprises the steps of: forming a metal layer on surface of the thin metal layer, and forming conductive columns in the openings; and removing the thin metal layer and the metal layer on the first surface and removing part of the conductive columns exposed above the second surface of the dielectric layer.

The fabrication method can further comprise forming at least a circuit build-up structure on surfaces of the dielectric layers and the circuit layers, wherein, the circuit build-up structure is electrically connected to the circuit layers. In addition, a dielectric protection layer can be formed on surface of the circuit build-up structure. The circuit build-up structure comprises a dielectric layer, a circuit layer stacked on the dielectric layer, and conductive structures formed in the dielectric layer.

Through the above fabrication method, a circuit board is obtained, which comprises: a core board having a plurality of openings formed therein; conductive columns formed in the openings of the core board; dielectric layers formed on two surfaces of the core board, wherein, the dielectric layers have a plurality of openings formed corresponding in position to the conductive columns; and circuit layers formed on surfaces of the dielectric layers, conductive structures being formed in the openings of the dielectric layer and electrically connected to the conductive columns of the core board such that the circuit layers are electrically connected together through the conductive columns of the core board.

The circuit board structure can further comprise at least a circuit build-up structure formed on surfaces of the dielectric layers and the circuit layers, and the circuit build-up structure is electrically connected to the circuit layers. A dielectric protection layer can be formed on outer surface of the circuit build-up structure. The circuit build-up structure comprises a dielectric layer, a circuit layer stacked on the dielectric layer, and conductive structures formed in the dielectric layer.

Another fabrication method disclosed by the present invention comprises the steps of: preparing a core board having a plurality of openings; forming conductive columns in the openings of the core board; and sequentially forming a dielectric layer and a circuit layer on one of the surfaces of the core board, and forming electrically conductive pads on the other surface of the core board corresponding in position to the conductive columns such that the electrically conductive pads are electrically connected to the circuit layer through the conductive columns in the core board.

Therein, a plurality of openings is formed in the dielectric layer corresponding in position to the conductive columns so as to form conductive structures in the openings while forming the circuit layer on the outer surface of the dielectric layer, thereby electrically connecting the conductive structures to the conductive columns.

In the above fabrication method, the electrically conductive pads can be formed before forming the dielectric layer and the circuit layer on the core board. The fabrication method of the electrically conductive pads comprises forming a metal layer on the first surface of the core board, and patterning the metal layer so as to form the electrically conductive pads.

In order to form the metal layer before forming the dielectric layer and the circuit layer, the core board can be a dielectric layer having a first and second surfaces with thin metal layers formed thereon, and a plurality of openings is formed in the dielectric layer penetrating through the thin metal layer on the second surface but without penetrating through the thin metal layer on the first surface. The fabrication method of the conductive columns in such a core board comprises the steps of: forming a metal layer on surfaces of the thin metal layers, and forming conductive columns in the openings; and removing the metal layer and the thin metal layer on the second surface. Subsequently, a patterned resist layer is formed on the metal layer on the first surface corresponding in position to the conductive columns; and the metal layer and the thin metal layer that are not covered by the patterned resist layer are removed so as to form the electrically conductive pads on the first surface of the dielectric layer; and removing the patterned resist layer.

According to another embodiment, the core board is a dielectric layer having a first and a second surfaces, a thin metal layer is formed on the first surface, and a plurality of openings is formed in the dielectric layer penetrating through the second surface but without penetrating through the thin metal layer on the first surface. A metal layer is formed on surface of the thin metal layer, and conductive columns are formed in the openings; and part of the conductive columns exposed above the second surface of the dielectric layer is removed. Subsequently, a patterned resist layer is formed on surface of the metal layer on the first surface of the dielectric layer corresponding in position to the conductive columns; the metal layer and the thin metal layer that are not covered by the patterned resist layer are removed so as to form the electrically conductive pads on the first surface of the dielectric layer; and the patterned resist layer is removed.

A circuit board structure obtained through the above fabrication method comprises: a core board having a plurality of openings formed therein; conductive columns formed in the openings of the core board; a dielectric layer formed on one surface of the core board, which has a plurality of opening formed corresponding in position to the conductive columns; a circuit layer formed on surface of the dielectric layer, conductive structures being formed in the openings of the dielectric layer and electrically connected to the conductive columns of the core board; and electrically conductive pads formed on the other surface of the core board corresponding to the conductive columns and electrically connected to the circuit layer through the conductive columns of the core board.

Because conventional electrically conductive pads are formed extending from ends of plating through holes and size of the electrically conductive pads is much bigger than that of the blind vias in dielectric layers, the development of high density circuit board structure is prevented. In addition, the fabrication cost is high. These drawbacks of the conventional art are overcome by the present invention by electrically connecting the circuit layers at two sides of the core board together through conductive columns without position deviation.

### BRIEF DESCRIPTION OF DRAWINGS

FIGS. 1A and 1B are sectional diagrams of conventional circuit board structures;

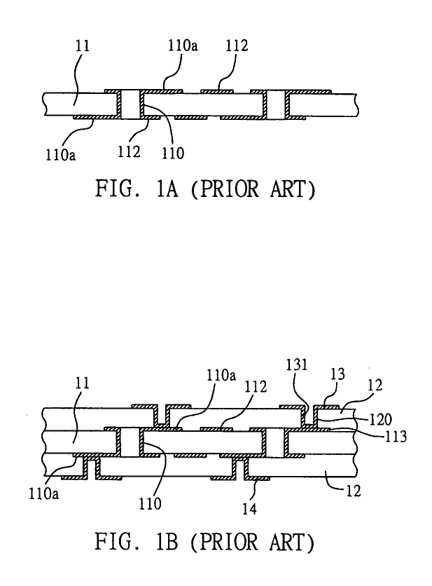

FIGS. 2A to 2G are sectional diagrams showing a circuit board structure and fabrication method thereof according to a first embodiment of the present invention;

FIG. 2F′ is a sectional diagram showing an alternative structure of FIG. 2F;

FIG. 3 is a sectional diagram showing a circuit board structure and fabrication method thereof according to a second embodiment of the present invention;

FIGS. 4A to 4D are sectional diagrams showing a circuit board structure and fabrication method thereof according to a third embodiment of the present invention;

FIGS. 5A to 5C are sectional diagrams showing a circuit board structure and fabrication method thereof according to a fourth embodiment of the present invention;

FIGS. 6A to 6D are sectional diagrams showing a circuit board structure and fabrication method thereof according to a fifth embodiment of the present invention; and

FIGS. 7A to 7D are sectional diagrams showing a circuit board structure and fabrication method thereof according to a sixth embodiment of the present invention.

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification. The present invention can also be performed or applied by other different embodiments. The details of the specification may be on the basis of different points and applications, and numerous modifications and variations can be made without departing from the spirit of the present invention.

### First Embodiment

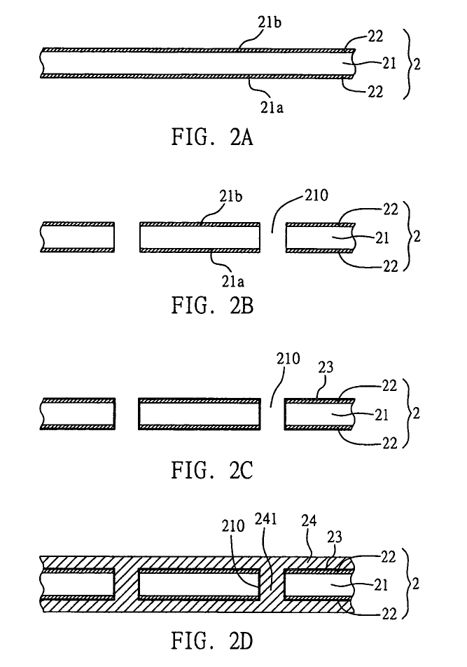

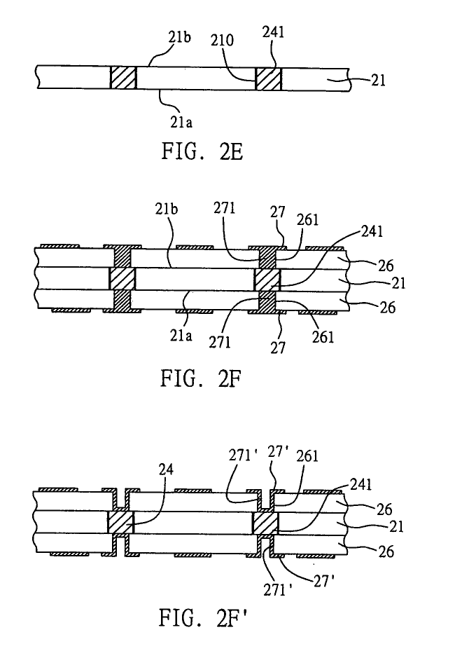

FIGS. 2A to 2F show a fabrication method of a circuit board structure according to a first embodiment of the present invention.

As shown in FIG. 2A, a core board 2 made of such as resin coated copper is prepared, which is a dielectric layer 21 having a first surface 21a and a second surface 21b. Thin metal layers 22 are respectively formed on the first surface 21a and the second surface 21b of the dielectric layer 21.

As shown in FIG. 2B, a plurality of openings 210 is formed in the core board 2 penetrating through the first and second surfaces 21a, 21b.

As shown in FIG. 2C, Conductive layers 23 are formed on surfaces of the core board 2 and in the openings 210. The conductive layers 23 may be made of a metal material or a conductive polymer. The conductive layers 23 mainly function as a current conductive path in an electroplating process as described later.

As shown in FIG. 2D, Metal layers 24 and a plurality of conductive columns 241 are formed on surfaces of the conductive layers 23 and in the openings 210. The metal layers 24 and the conductive columns 241 may be made of one of the group consisting of Pb, Sn, Ag, Cu, Au, Bi, Sb, Zn, Ni, Zr, Mg, In, Te, Ga and alloy thereof.

As shown in FIG. 2E, the metal layers 24, conductive layers 23 and the thin metal layers 22 are removed through a physical or chemical method. As a result, the conductive columns 241 are formed in the openings 210 of the dielectric layer 21.

As shown in FIG. 2F, dielectric layers 26 are respectively formed on the first surface 21a and the second surface 21b of the dielectric layer 21. A plurality of openings 261 is formed in the dielectric layers 26 corresponding in position to the plurality of conductive columns 241. Circuit layers 27 are formed on the dielectric layers 26 and conductive structures such as completely metal plated blind vias 271 electrically connected to the conductive columns 241 are formed in the openings 261. The circuit layers 27 can be formed through a patterning process. Since the patterning process is known in the art, detailed description of it is omitted.

FIG. 2F′ shows conductive structures according to another embodiment. As shown in FIG. 2F′, circuit layers 27′ are formed on the surfaces of the dielectric layers 26, and conductive blind vias 271′ electrically connected to the conductive columns 241 are formed in the openings 261.

Thus, the circuit layers 27 on the two surfaces of the core board 2 can be electrically connected together through the conductive structures such as the completely metal plated blind vias 271 or conductive blind vias 271′ and the conductive columns 241 that are aligned from up to down, thereby increasing the circuit layout density and eliminating the need of fabricating electrically conductive pads as in the conventional art and overcoming the conventional drawback of big interval caused by position deviation connection. Therefore, the present invention can be applied to ultra-thin, high-density IC substrate products such as PBGA, CSP, FCCSP and FCBGA.

As shown in FIG. 2G, at least a circuit build-up structure 28 can further be formed on surfaces of the circuit layers 27 and electrically connected to the circuit layers 27. The circuit build-up structure 28 comprises a dielectric layer 280, a circuit layer 282 stacked on the dielectric layer 280, and conductive structures 282a formed in the dielectric layer 280 electrically connected to one of the circuit layers 27. The conductive structures 282a can be such as completely metal plated blind vias or conductive blind vias. A dielectric protection layer 29 can further be formed on the outermost surface of the circuit build-up structure 28. The dielectric protection layer 29 has a plurality of openings 291 so as to expose electrically conductive pads 281 of outermost circuits of the circuit build-up structure 28. Conductive elements (not shown) can be mounted on the electrically conductive pads exposed from the openings of the dielectric protection layer such that the circuit board structure can be electrically connected to other devices.

Referring back to FIGS. 2F and 2F′, a circuit board structure is obtained according to the above-described fabrication method, which comprises: a core board 2 having a plurality of openings 210; a plurality of conductive columns 241 formed in the openings 210 of the core board 2; dielectric layers 26 formed on the two surfaces of the core board 2 and having a plurality of openings 261 formed corresponding in position to the conductive columns 241; and circuit layers 27,27′ formed on surfaces of the dielectric layers 26, wherein conductive structures such as completely metal plated blind vias 271 or conductive blind vias 271′ are formed in the openings 261 of the dielectric layers 26 and electrically connected to the conductive columns 241 of the core board 2. Thus, the circuit layers 27,27′are electrically connected together through the conductive columns 241 of the core board 2 so as to increase the circuit layer density.

### Second Embodiment

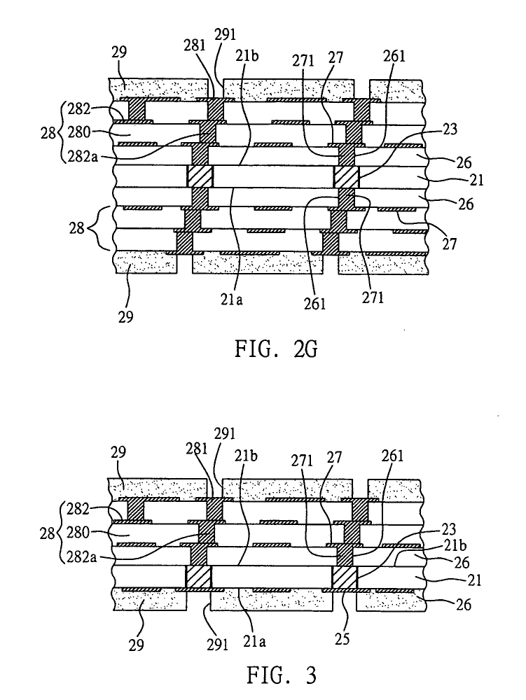

FIG. 3 shows a fabrication method of a circuit board structure according to the second embodiment of the present invention. Different from the first embodiment, a circuit layer 27 is formed on the second surface 21b of the dielectric layer 21, and electrically conductive pads 25 are formed on the first surface 21a of the dielectric layer 21. Therein, a metal layer (not shown) can first be formed on the first surface 21a of the dielectric layer 21 and then the metal layer is patterned through a conventional patterning process so as to form the electrically conductive pads 25. Thereafter, a circuit build-up structure 28 can be formed on the second surface 21b of the dielectric layer 21.

Subsequently, a dielectric protection layer 29 is formed on the first surface 21a of the dielectric layer 21 and on surfaces of the electrically conductive pads 25, and a plurality of openings 291 is formed therein so as to expose the electrically conductive pads 25. At least a circuit build-up structure 28 is formed on surface of the circuit layer 27 on the second surface 21b of the dielectric layer 21, and electrically connected to the circuit layer 27. A dielectric protection layer 29 is formed on the outermost surface of the circuit build-up structure 28, which has a plurality of openings 291 for exposing the electrically conductive pads 281 of outermost circuits of the circuit build-up structure 28. Conductive elements (not shown) can further be mounted to the electrically conductive pads in the openings of the dielectric protection layer.

Through the above fabrication process, a semiconductor substrate structure is obtained, comprising: a core board 2 having a first surface 21a and a second surface 21b, a plurality of openings 210 penetrating through the first and second surfaces 21a, 21b; conductive columns 241 formed in the openings 210 of the core board 2; a dielectric layer 26 formed on the second surface 21b of the core board 2 and having a plurality of openings 261 formed corresponding in position to the conductive columns 241; a circuit layer 27 formed on surface of the dielectric layer 26 and electrically connected to the conductive columns 241 in the core board 2 through conductive structures such as completely metal plated blind vias 271 or conductive blind vias 271′ formed in the openings 261 of the dielectric layer 26; and electrically conductive pads 25 formed on the first surface 21a of the core board 2 corresponding in position to the conductive columns 241.

A dielectric protection layer 29 is further formed on the first surface 21a of the dielectric layer 21 and the electrically conductive pads 25, and a plurality of openings 291 is formed in the dielectric protection layer 29 so as to expose the electrically conductive pads 25. A circuit build-up structure 28 is further formed on the second surface 21b of the dielectric layer 21, and a dielectric protection layer 29 is formed on the outer surface of the circuit build-up structure 28. The dielectric protection layer 29 has a plurality of openings 291 for exposing the electrically conductive pads 281 of outermost circuits of the circuit build-up structure 28.

### Third Embodiment

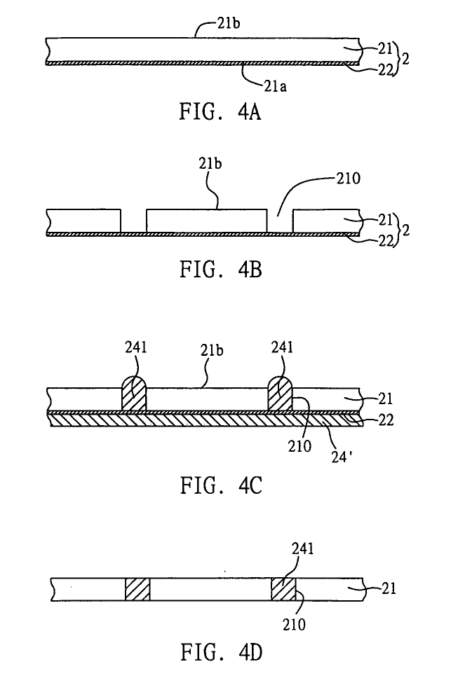

FIGS. 4A to 4D show a fabrication method of a circuit board structure according to a third embodiment of the present invention.

As shown in FIG. 4A, a core board 2 made of such as resin coated copper is prepared, which is dielectric layer 21 having a first surface 21a and a second surface 21b. A thin metal layer 22 is formed on the first surface 21a of the dielectric layer 21.

As shown in FIG. 4B, a plurality of openings 210 penetrating through the second surface 21b but without penetrating through the thin metal layer 22 is formed in the dielectric layer 21.

As shown in FIG. 4C, by using the thin metal layer 22 as a current conductive path, conductive columns 241 are formed in the openings 210 of the dielectric layer 21, and meanwhile a metal layer 24′ is formed on outer surface of the thin metal layer 22 through an electroplating process.

As shown in FIG. 4D, a part of conductive columns 241 exposed over the second surface 21b, the thin metal layer 22 on the first surface 21a of the dielectric layer 21, and the metal layer 24′ are removed. Thus, a plurality of conductive columns 241 is formed in the openings 210 of the dielectric layer 21.

Thereafter, dielectric layers, circuit layers and circuit build-up structures can respectively be formed on the first and second surfaces 21a, 21b of the dielectric layer 21.

### Fourth Embodiment

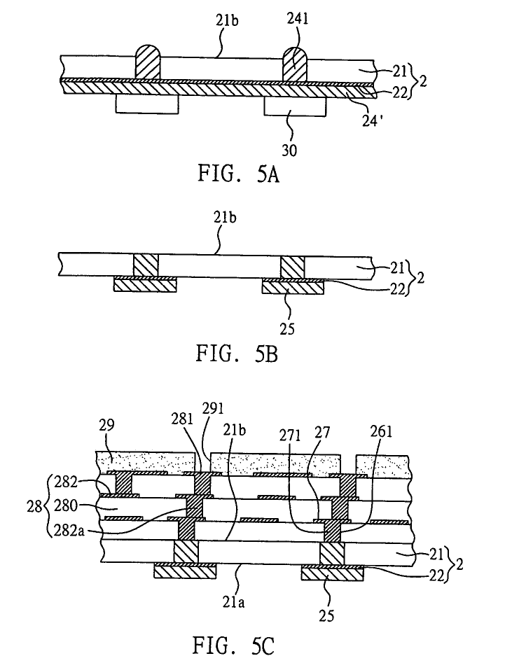

FIGS. 5A to 5C show a fabrication method according to a fourth embodiment of the present invention. In the embodiment, electrically conductive pads are formed before forming the dielectric layer and the circuit layer.

As shown in FIG. 5A, as a succession of FIG. 4C, a patterned resist layer 30 is formed on the metal layer 24′ corresponding in position to the conductive columns 241.

As shown in FIG. 5B, the metal layer 24′ and the thin metal layer 22 that are not covered by the patterned resist layer 30, and part of the conductive columns 241 exposed above the second surface 21b of the dielectric layer 21 are removed by such as etching. Thus, electrically conductive pads 25 are formed on the first surface 21a of the dielectric layer 21 and conductive columns 241 are formed in the dielectric layer 21. If necessary, thickness of the electrically conductive pads 25 can be decreased through a thinning process.

As shown in FIG. 5C, a dielectric layer 26, a circuit layer 27 and a circuit build-up structure 28 are formed on the second surface 21b of the dielectric layer 21. Therein, the circuit build-up structure 28 comprises a dielectric layer 280, a circuit layer 282 stacked on the dielectric layer 280, and conductive structures 282a formed in the dielectric layer 280 for electrically connecting the circuit layer 282 to the circuit layer 27 below the dielectric layer. The conductive structures 282a can be completely metal plated blind vias or conductive blind vias. A dielectric protection layer 29 is further formed on outer surface of the circuit build-up structure 28, and a plurality of openings 291 if formed in the dielectric protection layer 29 so as to expose electrically conductive pads 281 of outermost circuits of the circuit build-up structure 28. Conductive elements (not shown) can further be mounted to the electrically conductive pads exposed from the dielectric protection layer for electrical connection between the circuit board structure and other devices.

### Fifth Embodiment

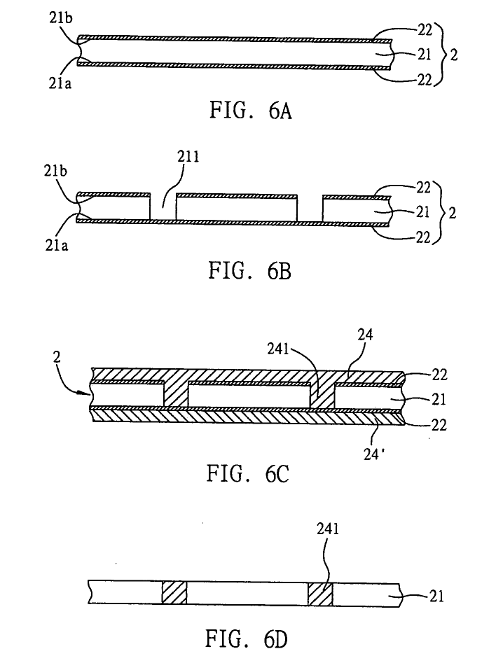

FIGS. 6A to 6D show a fabrication method of a circuit board structure according to a fifth embodiment of the present invention.

As shown in FIG. 6A, a core board 2 made of resin coated copper is prepared, which is a dielectric layer 21 having a first surface 21a and a second surface 21b. Thin metal layers 22 are respectively formed on the first surface 21a and the second surface 21b.

As shown in FIG. 6B, a plurality of openings 210 is formed in the dielectric layer 21 penetrating through the second surface 21b but without penetrating through the thin metal layer 22 on the first surface 21a.

As shown in FIG. 6C, by using the thin metal layer 22 as a current conductive path, a metal layer 24 is formed on the second surface 21b of the dielectric layer 21, conductive columns 241 is formed in the openings 210, and meanwhile another metal layer 24′ is formed on outer surface of the thin metal layer 22 through an electroplating process.

As shown in FIG. 6D, the metal layer 24 on the second surface 21b of the dielectric layer 21, the thin metal layer 22 and the metal layer 24′ on the first surface 21a of the dielectric layer 21 are removed. Thereby, a plurality of conductive columns 241 is formed in the openings 210 of the dielectric layer 21. The subsequent fabrication processes are same as the above-described processes and detailed description of them is omitted.

### Sixth Embodiment

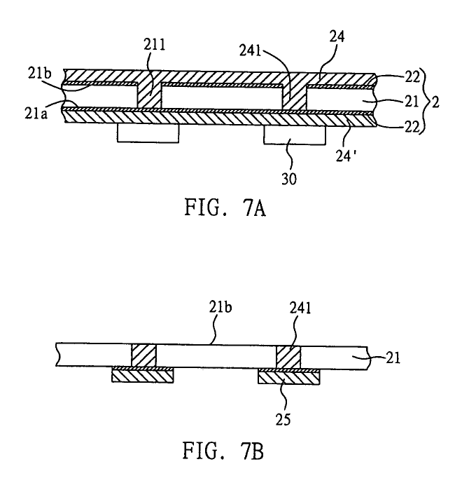

FIGS. 7A to 7D show a fabrication method of a circuit board structure according to a sixth embodiment of the present invention.

As shown in FIG. 7A, as a succession of FIG. 6C, a patterned resist layer 30 is formed on surface of the metal layer 24′ corresponding in position to the conductive columns 241.

As shown in FIG. 7B, the metal layer 24′ and the thin metal layer 22 that are not covered by the patterned resist layer 30 are removed by such as etching, and the thin metal layer 22 and the metal layer 24 on the second surface 21b of the dielectric layer 21 are removed. Thus, electrically conductive pads 25 are formed on the first surface 21a of the dielectric layer 21, and conductive columns 241 are formed in the dielectric layer 21. If necessary, thickness of the electrically conductive pads 25 can be decreased through a thinning process.

Thereafter, a dielectric layer, a circuit layer and a circuit build-up structure can be formed on the second surface 21b of the dielectric layer 21.

Therefore, according to the present invention, the circuit layout density of circuit board structures is increased, and the fabrication cost is reduced.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A fabrication method of a circuit board structure, comprising the steps of:
preparing a core board having a plurality of openings;
forming conductive columns in the openings of the core board;
forming dielectric layers on surfaces of the core board;
forming a plurality of openings in the dielectric layers corresponding in position to the conductive columns; and
forming circuit layers on surfaces of the dielectric layers and forming conductive structures electrically connected to the conductive columns in the openings of the dielectric layers such that the circuit layers are electrically connected together through the conductive columns of the core board.

2. The fabrication method of claim 1, wherein the core board is a dielectric layer having a first surface and a second surface with thin metal layers formed thereon, a plurality of openings being formed in the dielectric layer penetrating through the thin metal layers on the first and second surfaces of the dielectric layer.

3. The fabrication method of claim 2, wherein the fabrication method of the conductive columns comprises the steps of:
forming conductive layers in the openings of the dielectric layers and on surfaces of the thin metal layers;
forming metal layers on surfaces of the conductive layers and forming conductive structures in the openings; and
removing the metal layers, conductive layers and thin metal layers on the first and second surfaces of the dielectric layer.

4. The fabrication method of claim 1, wherein the core board is a dielectric layer having a first and a second surfaces with thin metal layers formed thereon, a plurality of openings being formed in the dielectric layer penetrating through the thin metal layer on the second surface but without penetrating through the thin metal layer on the first surface.

5. The fabrication method of claim 4, wherein the fabrication method of the conductive columns comprises the steps of:
forming metal layers on surfaces of the thin metal layers, and forming conductive columns in the openings; and
removing the metal layers and the thin metal layers on the first and second surfaces.

6. The fabrication method of claim 1, wherein the core board is a dielectric layer having a first and a second surfaces, a thin metal layer being formed on the first surface and a plurality of openings being formed in the dielectric layer penetrating through the second surface but without penetrating through the thin metal layer on the first surface.

7. The fabrication method of claim 6, further comprising:
forming a metal layer on surface of the thin metal layer, and forming conductive columns in the openings; and
removing the thin metal layer and the metal layer on the first surface of the dielectric layer, and part of the conductive columns exposed above the second surface of the dielectric layer.

8. The fabrication method of claim 1, further comprising forming at least a circuit build-up structure on surfaces of the dielectric layers and the circuit layers, the circuit build-up structure being electrically connected to the circuit layers.

9. The fabrication method of claim 8, further comprising forming a dielectric protection layer on surface of the circuit build-up structure, and forming a plurality of openings in the dielectric protection layer so as to expose electrically conductive pads in the circuit build-up structure for electrical connection.

10. The fabrication method of claim 8, wherein the circuit build-up structure comprises a dielectric layer, a circuit layer stacked on the dielectric layer, and conductive structures formed in the dielectric layer.

11. The fabrication method of claim 1, wherein each of the conductive structures is one of a completely metal plated blind via and a conductive blind via.

12. A fabrication method of a circuit board structure, comprising the steps of:
preparing a core board having a plurality of openings;
forming conductive columns in the openings of the core board; and
sequentially forming a dielectric layer and a circuit layer on one of the surfaces of the core board, and forming electrically conductive pads on the other surface of the core board corresponding in position to the conductive columns such that the electrically conductive pads are electrically connected to the circuit layer through the conductive columns in the core board.

13. The fabrication method of claim 12, wherein a plurality of openings is formed in the dielectric layer corresponding in position to the conductive columns so as to form conductive structures in the openings while forming the circuit layer on the outer surface of the dielectric layer, thereby electrically connecting the conductive structures to the conductive columns.

14. The fabrication method of claim 13, wherein the core board is a dielectric layer having a first surface and a second surface with thin metal layers formed thereon, a plurality of openings being formed in the dielectric layer penetrating through the thin metal layers on the first and second surfaces of the dielectric layer.

15. The fabrication method of claim 14, wherein the fabrication method of the conductive columns comprises the steps of:
forming conductive layers in the openings of the dielectric layers and on surfaces of the thin metal layers;
forming metal layers on surfaces of the conductive layers and forming conductive structures in the openings; and
removing the metal layers, conductive layers and thin metal layers on the first and second surfaces of the dielectric layer.

16. The fabrication method of claim 12, wherein the electrically conductive pads are formed before forming the dielectric layer and the circuit layer.

17. The fabrication method of claim 16, wherein the fabrication method of the electrically conductive pads comprises forming a metal layer on the first surface of the core board, and patterning the metal layer so as to form the electrically conductive pads.

18. The fabrication method of claim 16, wherein the core board is a dielectric layer having a first and second surfaces with thin metal layers formed thereon, a plurality of openings being formed in the dielectric layer penetrating through the thin metal layer on the second surface but without penetrating through the thin metal layer on the first surface.

19. The fabrication method of claim 18, wherein the fabrication method of the conductive columns comprises the steps of:
forming a metal layer on surfaces of the thin metal layers, and forming conductive columns in the openings; and
removing the metal layer and the thin metal layer on the second surface.

20. The fabrication method of claim 19, wherein the fabrication method of the electrically conductive pads comprises the steps of:
forming a patterned resist layer on surface of the metal layer on the first surface;
removing the metal layer and the thin metal layer that are not covered by the patterned resist layer so as to form the electrically conductive pads on the first surface of the dielectric layer; and
removing the patterned resist layer.

21. The fabrication method of claim 16, wherein the core board is a dielectric layer having a first and a second surfaces, a thin metal layer being formed on the first surface and a plurality of openings being formed in the dielectric layer penetrating through the second surface but without penetrating through the thin metal layer on the first surface.

22. The fabrication method of claim 21, wherein the fabrication method of the conductive columns comprises the steps of:
forming a metal layer on surface of the thin metal layer, and forming conductive columns in the openings; and
removing part of the conductive columns exposed above the second surface of the dielectric layer.

23. The fabrication method of claim 22, wherein the fabrication method of the electrically conductive pads comprises the steps of:
forming a patterned resist layer on surface of the metal layer on the first surface of the dielectric layer corresponding in position to the conductive columns;
removing the metal layer and the thin metal layer that are not covered by the patterned resist layer so as to form the electrically conductive pads on the first surface of the dielectric layer; and
removing the patterned resist layer.

24. The fabrication method of claim 12, further comprising forming at least a circuit build-up structure on surfaces of the dielectric layer and the circuit layer, the circuit build-up structure being electrically connected to the circuit layer.

25. The fabrication method of claim 24, further comprising forming a dielectric protection layer on outer surface of the circuit build-up structure, and forming a plurality of openings in the dielectric protection layer so as to expose the electrically conductive pads of the circuit build-up structure for electrical connection.

26. The fabrication method of claim 24, wherein the circuit build-up structure comprises a dielectric layer, a circuit layer stacked on the dielectric layer, and conductive structures formed in the dielectric layer.

27. The fabrication method of claim 12, wherein a dielectric protection layer is formed on surfaces of the core board and the electrically conductive pads, and a plurality of openings is formed in the dielectric protection layer so as to expose the electrically conductive pads.

28. The fabrication method of claim 12, wherein each of the conductive structures is one of a completely metal plated blind via and a conductive blind via.

29. A circuit board structure, comprising:
a core board having a plurality of openings formed therein;
conductive columns formed in the openings of the core board;
dielectric layers formed on two surfaces of the core board, wherein, the dielectric layers have a plurality of openings formed corresponding in position to the conductive columns; and
circuit layers formed on surfaces of the dielectric layers, conductive structures being formed in the openings of the dielectric layer and electrically connected to the conductive columns of the core board such that the circuit layers are electrically connected together through the conductive columns of the core board.

30. The circuit board structure of claim 29, further comprising at least a circuit build-up structure formed on surfaces of the dielectric layers and the circuit layers, and the circuit build-up structure is electrically connected to the circuit layers.

31. The circuit board structure of claim 30, further comprising a dielectric protection layer formed on outer surface of the circuit build-up structure, and a plurality of openings is formed in the dielectric protection layer so as to expose the electrically conductive pads in the circuit build-up structure for electrical connection.

32. The circuit build-up structure of claim 30, wherein the circuit build-up structure comprises a dielectric layer, a circuit layer stacked on the dielectric layer, and conductive structures formed in the dielectric layer.

33. The circuit build-up structure of claim 29, wherein each of the conductive structures is one of a completely metal plated blind via and a conductive blind via.

34. A circuit board structure, comprising:
a core board having a plurality of openings formed therein;
conductive columns formed in the openings of the core board;
a dielectric layer formed on one surface of the core board, which has a plurality of opening formed corresponding in position to the conductive columns;
a circuit layer formed on surface of the dielectric layer, conductive structures being formed in the openings of the dielectric layer and electrically connected to the conductive columns of the core board; and
electrically conductive pads formed on the other surface of the core board corresponding to the conductive columns and electrically connected to the circuit layer through the conductive columns of the core board.

35. The circuit board structure of claim 34, further comprising at least a circuit build-up structure formed on surface of the dielectric layer and the circuit layer, the circuit build-up structure being electrically connected to the circuit layer.

36. The circuit board structure of claim 35, further comprising a dielectric protection layer formed on surface of the circuit build-up structure, wherein, the dielectric layer has a plurality of openings formed therein for exposing the electrically conductive pads of the circuit build-up structure for electrical connection.

37. The circuit board structure of claim 35, wherein the circuit build-up structure comprises a dielectric layer, a circuit layer stacked on the dielectric layer, and conductive structures formed in the dielectric layer.

38. The circuit board structure of claim 34, wherein each of the conductive structures is one of a completely metal plated blind via and a conductive blind via.
